(19) United States
(12) Patent Application Publication
(10) Pub. No.: US 2017/0317231 A1
(43) Pub. Date: Nov. 2, 2017

(54) METHOD OF DETACHING A SUBSTRATE, DEVICE THAT CARRIES OUT SUCH A METHOD AND PUMPING DEVICE THAT PUMPS ETCHING SOLUTION

(71) Applicant: OSRAM Opto Semiconductors GmbH, Regensburg (DE)

(72) Inventors: Petrus Sundgren, Lappersdorf (DE); Marco Englhard, Regensburg (DE); Martin Rudolf Behringer, Regensburg (DE); Christoph Klemp, Regensburg (DE)

(21) Appl. No.: 15/523,014

(22) PCT Filed: Oct. 27, 2015
(86) PCT No.: PCT/EP2015/074875

§ 371 Date: Apr. 28, 2017

(30) Foreign Application Priority Data
Oct. 30, 2014 (DE) 10 2014 115 799.0

(51) Int. Cl. H01L 33/00; H01L 23/00; C23F 1/20

(52) U.S. Cl. CPC H01L 33/0079; C23F 1/20; H01L 24/95

(57) ABSTRACT

A method of debonding a substrate from a layer sequence includes a) providing a composite including a wafer with the substrate, the layer sequence applied to a growth surface of the substrate, and a sacrificial layer arranged between the substrate and the layer sequence, a carrier on a cover surface of the layer sequence facing away from the substrate, and at least two separating trenches extending in the vertical direction through the layer sequence and to and/or through the sacrificial layer, b) attaching a pumping device on the composite and forming a second direct flow path between the separating trenches and the pumping device, c) introducing the composite into an etching bath with an etching solution, d) generating a pressure gradient between separating trenches and the etching solution, and e) debonding the substrate.

### TECHNICAL FIELD

This disclosure relates to a method of detaching a substrate, a device that carries out such a method and a pumping device that pumps etching solution.

### BACKGROUND

DE 197 34 635 A1 describes a method of debonding a substrate as well as a device that performs such a method. There is nonetheless a need to provide a simplified method of non-destructive debonding of a substrate from a layer sequence and a device that performs such a method as well as a pumping device that pumps etching solution.

### SUMMARY

We provide a method of debonding a substrate from a layer sequence including:

a) providing a composite including a wafer with the substrate, the layer sequence applied to a growth surface of the substrate and provided for implementation in a light-emitting diode chip, and a sacrificial layer arranged between the substrate and the layer sequence, a carrier on a cover surface of the layer sequence facing away from the substrate, and at least two separating trenches extending in the vertical direction through the layer sequence and to and/or through the sacrificial layer, wherein at least one first direct flow path runs through the at least two separating trenches from a first edge point on an exposed edge of the composite to an inner point of the composite,

b) attaching a pumping device on the composite and forming a second direct flow path between the separating trenches and the pumping device,

c) introducing the composite into an etching bath with an etching solution, wherein the composite is covered by the etching solution at least in places, and at least one separating trench on the edge is completely in direct contact with the etching solution,

d) generating a pressure gradient between the separating trenches and the etching solution with the pumping device such that the etching solution flows through the two direct flow paths in places along the sacrificial layer, wherein the etching solution is in places in direct contact with the sacrificial layer, and

e) debonding the substrate, wherein prior to step b), exactly one hole is produced in the carrier and/or the layer sequence, and the pumping device connects to the hole in step b), the hole extends completely through the carrier and the layer sequence in a vertical direction and is introduced in the carrier and in the layer sequence at a center of the composite, and at least the second flow path runs through the hole.

We also provide a device that performs the method, the device including a pumping device having a vacuum pump, and at least one connecting flange connected to the vacuum pump and including at least one sealing element, and an etching bath with an etching solution, wherein the method includes:

a) providing a composite including a wafer with the substrate, the layer sequence, a sacrificial layer arranged between the substrate and the layer sequence, and at least two separating trenches extending in a vertical direction through the layer sequence and to or through the sacrificial layer,

b) attaching a pumping device on the composite,

c) introducing the composite into the etching bath,

d) generating a pressure gradient between the separating trenches and the etching solution with the pumping device, and

e) debonding the substrate,

the sealing element has a good chemical resistance toward the material of the etching solution, and the vacuum pump is configured to generate a pressure of at most 10³ Pa, in the volume generated by the separating trenches.

We further provide a pumping device that pumps etching solution, including a vacuum pump and a connecting flange connected to the vacuum pump via a vacuum hose, wherein the connecting flange includes a depression having a circular-segment-type cross section, the depression extends entirely to an exposed side surface of the connecting flange, wherein the chord of the circular-segment-type cross section is part of the side surface and the connecting flange includes a sealing element in the depression attached to the side surface.

### BRIEF DESCRIPTION OF THE DRAWINGS

FIGS. 1A, 1B, 1C, 2A, 2B, 2C, 2D, 2E show examples of a method described herein by schematic illustrations.

FIGS. 4A, 4B, 4C, 6A and 6B show examples of a method described herein as well as a device described herein by schematic illustrations.

FIGS. 3, 5A and 5B show examples of a method described herein as well as of a pumping device described herein by schematic illustrations.

### LIST OF REFERENCE NUMERALS

1 wafer
11 substrate
11a growth surface
12 sacrificial layer
13 layer sequence
13a cover surface
14 separating trench
14d width of a separating trench
3 carrier
20 hole
20d hole diameter
21 edge of the composite
22 inner point, center
3 pumping device
31 vacuum pump
32 connecting flange
33 groove
34 O-ring
35 vacuum hose
4 etching bath
41 etching solution
5, 5′ pressure gradient
6 segments
6b side surface of connecting flange
61 recess
61′ depression
61 chord
62a connecting surface
63 threaded bores
81 first direct flow path
82 second direct flow path
83 first edge point
84 second edge point
Z vertical direction

### DETAILED DESCRIPTION

We provide a method of debonding a substrate. The method is particularly suitable for separating a substrate from a layer sequence grown epitaxially on the substrate.

A composite may first be provided. The composite comprises a wafer, which comprises the substrate having a growth surface. Preferably, the substrate is a growth substrate suitable to epitaxially grow semiconductor layers. The substrate is formed with at least one crystalline material or consists of a crystalline material, for example. The crystalline material can be GaAs, Ge, Si and/or sapphire, for example.

The substrate comprises a main extension plane in which it extends along the growth surface in lateral directions. Perpendicular to the main extension plane, the substrate has a thickness in a vertical direction. The thickness of the substrate is small compared to the maximum extension of the substrate in a lateral direction.

A layer sequence is applied to the growth surface of the substrate. Preferably, the layer sequence is semiconductor layers epitaxially grown on the growth surface. The layer sequence is formed with a semiconductor compound material, for example. The III/V semiconductor compound material can be AlₓGa₁₋ₓAs or AlₓGa_{y}In_{1-x-y}P, for example, with 0≦(x,y)≦1 and x+y≦1. In particular, the layer sequence comprises an active layer that absorbs and/or emits light, or an integrated circuit. The layer sequence is provided for implementation in a light-emitting diode chip, a photo diode chip and/or a solar cell chip, for example.

A sacrificial layer is arranged between the substrate and the layer sequence. The layer sequence connects to the substrate by the sacrificial layer. Preferably, the layer sequence connects to the substrate by the sacrificial layer only. In other words, the layer sequence no longer connects to the substrate in a chemical decomposition of the sacrificial layer, and can be separated therefrom.

The sacrificial layer can be etched selectively to the layer sequence. In other words, at least one etching solution exists, which has a significantly higher etching rate with respect to the material of the sacrificial layer than with respect to the layer sequence. The etching solution may be a liquid such as an acid, for example, and/or a gas. In particular, the etching solution can be an etching medium. The sacrificial layer may comprise a high aluminum portion. In particular, the sacrificial layer can be formed with AlₙGa₁₋ₙAs, with 0.6≦n≦1, preferably 0.7≦n≦1, for example. This allows for the selective etchability of the sacrificial layer.

Furthermore, the composite comprises a carrier. The carrier is arranged on a cover surface of the substrate facing away from the layer sequence. The carrier has a main extension plane running along the main extension plane of the substrate. The lateral extensions of the carrier and the substrate may differ from one another by at most +/−10%, for example.

For example, the carrier mechanically connects to the layer sequence by a solder layer that may directly adjoin the cover surface and the carrier. As an alternative or in addition, it is possible for the carrier and the layer sequence to connect to one another by wafer bonding. The carrier can be formed with a ceramic, a plastic and/or a semiconductor material, for example. The carrier can be an electrical connection carrier, for example. The carrier may comprise connection points having an electrically-conductive design.

Furthermore, the composite comprises at least two separating trenches extending in a vertical direction through the layer sequence and to, into and/or through the sacrificial layer. The at least two separating trenches can be recesses in the layer sequence and the sacrificial layer. In particular, the at least two separating trenches can be laterally connected to one another. In other words, the at least two separating trenches may be of contiguous design in a top view. The separating trenches enclose regions of the layer sequence and of the sacrificial layer in a frame-like manner, for example. The regions of the layer sequence produced by the separating trenches may correspond to the corresponding chips, e.g. the light-emitting diode chips, photo diode chips or solar chips to be produced, for example. A “top view” of a component is a top view from the vertical direction of the component.

Furthermore, the separating trenches have a width given by the minimum extension of the separating trenches in at least one lateral direction. The width of the separating trenches is the minimum distance of two regions of the layer sequence and the sacrificial layer arranged next to one another and separated by the separating trenches, for example. The width of the at least two separating trenches is at least 5 μm and 100 μm at the most, for example. Along the vertical direction, the separating trenches have a height given by the combined thickness of the sacrificial layer and the thickness of layer sequence, for example.

At least one first direct flow path runs from a first edge point on an exposed edge of the composite through the at least two separating trenches to an inner point of the composite. In particular, the inner point is not located on the edge of the composite, but inside the composite. Preferably, the inner point is a center of the composite. The first direct flow path can extend from the first edge point to the center of the composite then. Preferably, the edge of the composite is a lateral outer surface of the composite. In a top view, the composite is, at least in places, of circular-disc-shaped design, i.e. in the type of a circular disc, for example. In effect, the edge of the composite is the perimeter of the circular-disc-type composite. Furthermore, in a top view, it is possible for the composite to be of polygonal design. Then, the edge of the composite is basically the exposed lateral outer surfaces of the composite.

An item has a “circular-disc-shaped” or “circular” design if the shape of the item deviates by at most 40%, preferably at most 20%, from the geometric shape of a circular disc or a circle in the mathematical sense. The deviation of the composite to the geometric shape of a circular disc or a circle may be given in that the composite, in a top view, has the shape of an ellipsis with an eccentricity of at most 0.15. It is further possible for the composite to comprise recesses or flat portions and that the edge of the composite does thus not follow the curvature of a circle and/or ellipsis. In addition, the composite may have an irregular thickness in the vertical direction, deviating in places by at most 20%, preferably at most 10%, from an average thickness of the composite.

Furthermore, the center of the composite corresponds to the geometrical center of the composite within the manufacturing tolerances. “Within the manufacturing tolerances” in this context means that the center of the composite may deviate from the maximum lateral extension of the composite by at most 10%, preferably at most 5%, of the maximum lateral extension of the composite. When the composite has a circular-disc-shaped design, the center therefore deviates by at most 10%, preferably at most 5%, of the diameter of the assigned circle from the center of this circle.

A “direct flow path is a connection between two points which are spaced apart from one another, wherein a flow of matter, in particular a flow of liquid and/or gas, is enabled through this connection. A “flowing” of matter may correspond to a “flow-through” through matter. In particular, the flow of matter through a direct flow path may be larger than the naturally-caused diffusion through the material enclosing the flow path. Therefore, a direct flow path may be a flow path that can be flown-through by matter, which path has a sufficiently large volume flow rate. A direct flow path may have a smallest cross section of at least 10 μm², preferably at least 500 μm², for example. In other words, a direct flow channel is not a so-called dead volume. It is in particular possible in this case to transport a liquid through the direct flow path in a set time, for example, in less than 10 minutes between two points spaced apart from one another.

The at least one first direct flow path extends from the first edge point on the edge through the at least one separating trench to the inner point of the composite. The first edge point is preferably directly arranged on a separating trench. The first direct flow path does not necessarily have to run on the direct or respectively shortest way from the edge to the inner point. It is possible, for example, for the first direct flow path to extend through multiple separating trenches. The assigned flow channel for the desired material flow through the flow path is given by at least one separating trench, through which the direct flow path runs. The smallest cross section can then be given by the dimensions of the separating trenches, in particular the width and height and equal at least 10 μm², preferably at least 500 μm².

A pumping device may be attached to the composite. The pumping device may comprise a compressor and/or a vacuum pump, for example. Attachment of the pumping device can be effected such that a negative pressure or an overpressure can be generated in separating trenches. The terms “negative pressure” and “overpressure” are to be understood as relative to the normal pressure of about 10⁵ Pa. The pumping device can be attached to the composite with a sealing element, for example.

A second direct flow path may be formed between the separating trenches and the pumping device. To that end, the pumping device is attached to openings in the composite, for example. The openings can be arranged on the edge of the composite and/or in the carrier, for example. The first and the second direct flow paths are preferably directly connected to one another and form a common direct flow path. In other words, preferably a direct flow path exits from the first edge point on the edge of the composite to the pumping device. In this case, the connection of the two flow paths can ensue on the inner point, preferably at the center of the composite. Alternatively or in addition, it is also possible, however, for the first direct flow path to open into the second direct flow path at a different point.

The composite may be introduced into an etching bath with an etching solution. The etching bath may particularly be a vessel filled with an etching solution, which may be a liquid. The etching solution may be an acid, e.g. a 10% hydrofluoric acid, for example. As an alternative or in addition, the etching bath may be a gas container filled with the etching solution, which may be a gas. The gas may be a caustic gas, hydrogen fluoride gas, for example. Hydrofluoric acid and/or hydrogen fluoride gas is in particular suitable as an etching solution for AlₙGa₁₋ₙAs, in particular AlAs and/or AlGaAs.

Introducing the composite into the etching bath is effected such that the composite is at least partially covered by the etching solution. In particular, at least one separating trench on the edge is in direct contact with the etching solution. Preferably, the first direct flow path is in direct contact with the etching solution. Advantageously, a direct flow path from the etching solution into the first direct flow path is produced.

A pressure gradient may be generated between the separating trenches and the etching solution by the pumping device after introduction of the composite into the etching bath. The pressure gradient may in particular be generated during at least 80% of the etching process, i.e. during at least 80% of the duration during which the composite is introduced into the etching solution. The pressure gradient is an overpressure and/or a negative pressure inside the composite. In this case, air may be suctioned by the pumping device and, therefore, a negative pressure can be generated in the composite, whereby the etching solution is suctioned into the pumping device from the etching bath through the separating trenches, i.e. into the first direct flow path. It is furthermore possible to produce an overpressure in the etching solution by the pumping device, and that the etching solution is pressed through the separating trenches, for example.

Due to the pressure gradient, the etching solution flows through the first direct flow path and/or the second direct flow path. In particular, the etching solution is in particular suctioned and/or pumped through the two direct flow paths due to the generated pressure gradient. The etching solution flows in places along the sacrificial layer and is in direct contact therewith at least in places. In particular, a chemical reaction of the etching material with the material of the sacrificial layer is enabled by the direct contact. The sacrificial layer can thereby be chemically dissolved.

The substrate may be debonded. The layer sequence is attached to the carrier then. Preferably, debonding is effected at the time when the sacrificial layer is separated by at least 95% in a lateral and/or vertical direction. The substrate can be debonded from the sacrificial layer in a non-destructive manner thereby. “Non-destructive” refers to the substrate as well as to the layer sequence. The substrate can then be used again for epitaxial growth of a layer sequence, for example.

The method of debonding a substrate from a layer sequence may comprise:

a) providing a composite comprising a wafer having the substrate, the layer sequence, which is attached to a growth surface of the substrate, and a sacrificial layer arranged between the substrate and the layer sequence, a carrier on a cover surface of the layer sequence facing away from the substrate and at least two separating trenches extending in a vertical direction through the layer sequence and to and/or through the sacrificial layer. At least one first direct flow path runs through the at least two separating trenches from a first edge point on an exposed edge of the composite to an inner point of the composite.

b) attaching a pumping device on the composite and forming a second direct flow path between the separating trenches and the pumping device,

c) introducing the composite into an etching bath with an etching solution, wherein the composite is at least in places covered by the etching solution, and at least one separating trench on the edge is completely in direct contact with the etching solution,

d) generating a pressure gradient between the separating trenches and the etching solution with the pumping device such that the etching solution flows through the two direct flow paths in places along the sacrificial layer, wherein the etching solution is in places in direct contact with the sacrificial layer, and

e) debonding the substrate.

In particular, method steps a) to e) can be performed in the indicated order.

The method of debonding the substrate in particular pursues the idea of allowing a better flow-through of the etching solution through the separating trenches by applying a pressure gradient between the separating trenches and the etching solution. It is furthermore possible by the method described herein to remove the etching products generated during the etching process, e.g. developing gases and/or salts, to be removed from the separating trenches by applying the pressure gradient. A process time may be reduced thereby and the etching result can be improved.

In a method in which no pressure gradient is generated during the etching process and/or the etching liquid, respectively the etching medium, is suctioned into the separating trenches merely by capillary forces, in particular the problem could occur that the etching solution does not completely and/or only slowly reach the sacrificial layer. The chemical reaction between the etching solution and the sacrificial layer would proceed only slowly. The etching result would be incomplete then, which is why no destruction-free debonding of the substrate would be possible. An evacuation of the volume in the separating trenches prior to introduction into the etching solution would not succeed here since air bubbles would be trapped in the composite, which would not be able to escape.

Furthermore, in particular when producing photovoltaic chips, the problem occurs that large substrates, which could be formed of expensive materials, are required. In this case, the nondestructive debonding of the substrate, and thus the possibility of re-using it, is particularly advantageous with a method used herein.

The at least one first direct flow path may be guided further from the inner point of the composite through the at least one separating trench to a second edge point. The second edge point is arranged on the side of the edge opposite the first edge point relative to a center of the composite. Thus, at least one first direct flow path extends from one edge of the composite to the opposite edge. In particular, the first direct flow path may extend through multiple separating trenches and run through multiple points on the edge of the composite. Preferably, the composite is homogenously pervaded by first direct flow paths within the manufacturing tolerances. The etching solution may advantageously be introduced into the separating trenches on the first edge point and the second edge point. In particular, the first edge point and the second edge point are in direct contact with the etching solution.

The processing time of steps b) to d), required for complete debonding of the substrate, may total at most 1.5 hours, preferably at most 1 hour. In other words, steps b) to d) are performed during a time period of at most 1.5 hours, preferably at most 1 hour. The processing time is in particular the time that the composite needs to remain in the etching solution to allow a complete and non-destructive debonding of the substrate from the layer sequence. The process time is in particular the time required for separating the sacrificial layer in at least a lateral direction.

The process time of steps b) to d) may total at most half of the process time required to completely debond the substrate with a method in which no pressure gradient is generated in step c). In other words, our method can be performed at least twice as fast as a method in which no pressure gradient is generated during the etching process. Our method is characterized by a reduced process time for the non-destructive debonding of the substrate. The process time is reduced in particular by generating the pressure gradient and the resulting increased flow rate of the etching solution through the separating trenches.

A negative pressure may be generated in the separating trenches in step d). In particular, the negative pressure may be generated by the pumping device, e.g. by suctioning. Generation of the negative pressure is effected such that a negative pressure is at least 10⁻¹ Pa and at most 10⁴ Pa, preferably at most 10³ Pa, in a composite which apart from the fact that merely a connection of the first direct flow path to the second direct flow path exists, but no direct flow path to the outside, is constructionally identical. In other words, if there was no flow path in the etching solution, this negative pressure would prevail in the composite. The etching solution is suctioned into the first and the second direct flow path by generation of the negative pressure, for example. The etching solution flows out of the etching bath then through the separating trenches into the pumping device. Furthermore, it possible here that reaction products such as gas and/or salts produced in chemical etching of the sacrificial layer are also suctioned from the separating trenches.

An overpressure may be generated in the etching solution to produce the pressure gradient in step d). It is possible here for the etching solution to be pressed through the first direct flow path into the second direct flow path by an overpressure that can be generated by a compressor, for example. In other words, the etching solution is pumped into the separating trenches.

It is further possible that both a negative pressure in the separating trenches and an overpressure in the etching solution is generated. The etching solution is first pumped into the separating trenches then, i.e. into the first direct flow path, and at the same time suctioned into the separating trenches and into the pumping device. This combination of an overpressure and a negative pressure can additionally increase the flow rate of the etching solution through the separating trenches.

At least one hole may be produced in the carrier prior to step b). The hole may be a recess in the carrier. Preferably, the hole extends completely through the carrier in a vertical direction. The layer sequence is freely accessible on its cover surface through the hole.

As an alternative or in addition, it is possible for another hole to be produced in the layer sequence prior to step b). The further hole may be a recess in the layer sequence. The further hole may extend completely through the layer sequence in the vertical direction. In other words, a hole can be produced in the carrier and/or in the layer sequence prior to step b), with the hole extending completely through the carrier and/or the layer sequence in the vertical direction. The growth surface for the substrate can be freely accessible through the further hole.

It is possible for the hole and/or the further hole to be introduced into the carrier or the further hole before connecting, in particular before wafer-bonding the layer sequence with the carrier. As an alternative, it is possible to first connect the layer sequence and the carrier and subsequently introduce the hole and/or the further hole into the carrier or the layer sequence, respectively.

The further hole may be formed identically to the hole. In other words, the further hole may also have the features and properties disclosed for the hole in the following, where the indication of features for the hole is to be understood as referring to the carrier and for the further hole as referring to the layer sequence. In particular, the method steps explained or performed hereinafter in conjunction with the hole may alternatively or additionally be performed to the further hole.

The pumping device connects to the hole after having produced the hole in step b). The second direct flow path runs through the hole. In other words, a direct flow path exists from the first edge point on the edge of the composite through the separating trenches through the hole into the pumping device. In this case, a uniform pressure gradient can be generated across the entire composite. In particular, a uniform pressure gradient may prevail along the edge of the composite. The term “uniform pressure gradient” is to be understood as being within the scope of manufacturing tolerances. The pressure gradient may vary along the edge of the composite by +/−10%, for example.

The pressure gradient may be a negative pressure, for example, that can be generated by suctioning by the pumping device on the hole. It is possible for a flow direction of the etching solution to run from the edge of the composite to the center. In other words, the etching solution is suctioned into the pumping device through the hole. Alternatively, an overpressure can be generated on the hole by the pumping device and/or the etching solution can be pumped into the hole. In this case, the flow direction of the etching solution may run from the hole to the edge.

Each separating trench may have a width of at least 0.2%, preferably at least 2%, and at most 50%, preferably at most 20%, of a diameter of the hole. The diameter of the hole can be the maximum lateral extension of the hole. Preferably, the diameter of the hole is the average lateral extension of the hole. The diameter of the hole is at least 0.5 mm and at most 2 mm, for example. In particular, it is possible for the hole to have a circular cross section. In other words, the shape of the hole deviates from the shape of a circle in the mathematical sense by at most 20%, preferably by at most 10%. The diameter of the hole is the diameter of the circle assigned to the circular-type cross section. The width of the at least two separating trenches may be at least 20 μm and at most 100 μm. By selecting the diameter of the hole depending on the width of the separating trenches, in particular, a good volume flow rate from the first direct flow path into the second direct flow path can be made possible.

At least one hole may be introduced at the center into the carrier and/or into the layer sequence. The center is part of the hole then. By arranging the hole at the center, a uniform pressure gradient can be generated over the entire composite. Alternatively or in addition, it is possible for the at least one hole to be arranged at a distance from the center. Multiple holes, preferably equally distributed laterally, can be arranged in the carrier and/or in the layer sequence, for example.

The pumping device may connect laterally to the composite. The first flow path and/or the second flow path run through at least 10% of the edge of the composite then. The pumping device connects at a first lateral side of the composite, whereas the second lateral side opposite the first lateral side with respect to the center of the composite is immersed into the etching solution. It is possible for at least 10% of the edge of the composite to be introduced into the etching solution on the second lateral side. Preferably, at least 50%, preferably at least 60%, of the edge and/or the composite are introduced into the etching solution. By laterally connecting the pumping device, a negative pressure is generated on the first lateral side of the edge of the composite by the pumping device. The negative pressure can be transmitted further to the second lateral side of the composite via the first direct flow path.

Furthermore, we provide a device that performs a method of debonding a substrate from a layer sequence. The device is provided for a method described herein. In other words, all features disclosed for the method are also disclosed for the device and vice versa.

The device may comprise the pumping device. The pumping device comprises a vacuum pump and a connecting flange connected to the vacuum pump. The connecting flange connects to the vacuum pump by a vacuum hose, for example. The vacuum hose does not necessarily have to be a mechanically-flexible hose. Rather, the vacuum hose can also be configured as a rigid pipe. A vacuum hose is particularly characterized by its tightness, in this case at a negative pressure of at most 10⁴ Pa inside the hose. The mechanical connection between the connecting flange and the vacuum pump is effected in accordance with the pressure gradient to be produced.

The connecting flange comprises at least one sealing element. The sealing element can be a groove with an O-ring introduced therein. The O-ring may be an annular-shaped or torus-shaped sealing element, for example. In particular, the groove is a depression introduced into the connecting flange provided to receive the O-ring. Furthermore, the connecting flange having the sealing element can be a suction cup. Furthermore, it is possible for the connecting flange to be attached to the carrier by an adhesive as the sealing element. According to the method, the adhesive or the connecting flange, respectively, can be removed with a solvent after the method.

The device may further comprise the etching bath. The sealing element has a good chemical resistance toward the material of the etching solution. In other words, the service life of the sealing element is reduced by at least 10% in a longer lasting contact with the etching solution, compared to a sealing element which is identical in construction apart from the fact that it did not have any contact with the etching solution.

The vacuum pump is configured to generate a pressure of at most 10⁴ Pa, preferably at most 10³ Pa, in the volume produced by the separating trenches. In other words, a pressure of at most 10⁴ Pa, preferably at most 10³ Pa can be produced in the volume of the separating trenches having the respective volume flow rate in a time period of preferably at most two hours, for example. To that end, the vacuum pump has a suction performance required corresponding to the volume and the volume flow rate of the separating trenches. A water jet pump, a membrane pump and/or a scroll pump are suitable as a vacuum pump, for example.

The device may comprise two segments. Each segment of the connecting flange comprises a recess. At least one of the recesses has a circular-segment-type shape in a top view of the segment. A top view of the segment is a top view of the side of the segment comprising the recess. Furthermore, a “circular-segment-type shape” is a shape following a circular segment by at least 80%, preferably at least 90%. Furthermore, at least one of the segments may comprise a groove, the groove introduced in the segment on the chord of the circular-segment-type shape. The chord of the circular-segment-type shape of the recess is the straight side of the circular-segment-type shape. The chord is formed by a side surface of the segment and/or the connecting flange, in particular.

The two segments connect in a mechanically releasable manner on their connection surfaces comprising the respective recess. In other words, the recesses of the two segments face each other. Together, the two recesses form a depression in the connecting flange. The depression may be freely accessible and in particular open on the side surface of the connecting flange comprising the chord of the recess. A “mechanically releasable connection” may be characterized by the fact that the connection of the two components can be separated from one another in a non-destructive manner and without using a solvent. The connection which is mechanically releasable is effected by connecting pins, screw-connections and/or plug connections. To that end, the segments may comprise threaded bores, through which a screw and/or a connecting pin can be guided.

The connecting flange is configured to partially receive the composite between the two segments in the two recesses, i.e. in the depression, and to seal it toward the outside. In other words, the composite can be introduced in the depression formed by the two recesses and be sealed by a sealing element that can be an O-ring introduced in the groove of the segments, for example. The composite is squeezed in the depression with the sealing element, for example. The sealing element may be in direct contact with the composite and enclose the composite in a vertical direction then.

The recesses are preferably configured such that the depression formed by the recesses may at least partially receive the composite having a preferably circular-segment-type shape with the manufacturing tolerances. In other words, the circle corresponding to the circular-segment-type shape of the recesses has the same diameter, in places, as the circle assigned to the composite. It is possible that a dead volume be present between the composite and a hose leading to the vacuum pump. Furthermore, the recess may have a depth perpendicular to the circular-segment-type shape, which, in within the manufacturing tolerances, corresponds to at least 55% of the thickness of the composite and at most 80% of the thickness of the composite.

The two segments may be designed to be mirror-symmetrical relative to one another within the manufacturing tolerances. The term “mirror-symmetrical” is to be understood as being within manufacturing tolerances. In other words, deviations from the mirror symmetry may be possible due to manufacture. In particular, in the mirror-symmetrical configuration, both recesses may have a circular-segment-type shape in a top view. In particular, the optionally-present grooves of the segments may be superimposing on one another in a top view. Furthermore, the circle arcs, i.e. the curved sides, of the recesses may be in direct contact with one another.

The connecting flange may have a circular-type design in a top view, and is configured to completely enclose the hole with the sealing element laterally and seal it toward the outside. In particular, the connecting flange and/or the sealing element can be in direct contact with a base surface of the carrier facing away from the substrate. The connecting flange may comprise a vacuum flange, put over the hole, with the hole enclosed by the sealing element introduced into the vacuum flange, the sealing element being an O-ring, a sealing adhesive and/or a suction cup, for example. The connecting flange comprises a groove, for example, the groove having a circular shape with a diameter at least twice as large as the diameter of the hole into which the O-ring is introduced.

We also provide a pumping device that pumps etching solution. In particular, the pumping device is configured for implementation in a device described herein to perform a method described herein. In other words, all features disclosed for the method and the device are disclosed for the pumping device and vice versa as well.

The device may comprise a vacuum pump. The pumping device further comprises a connecting flange. The connecting flange is connected to the vacuum pump by a vacuum hose.

The connecting flange comprises a depression with a circular-segment-type cross section. The depression extends all the way to an exposed side surface of the connecting flange. The side surface of the connecting flange forms the chord of the circular-segment-type cross section of the depression. In other words, the side surface particularly is a straight surface.

The connecting flange comprises a sealing element in the depression attached to the side surface. The sealing element is, in particular, attached near the side surface. In other words, the sealing element can be arranged at a small distance of at least 1 mm and at most 10 mm, to the side surface, for example. The sealing element may be an O-ring introduced into a groove, for example. In this way, a continuous sealing of the depression can be effected by the O-ring.

The depression of the connecting flange is configured for at least partially receiving a circular-type disc. The circular-type disc can be the composite described herein, for example. In other words, the composite described herein can be squeezed in the depression. Squeezing is effected by the sealing element, for example. Incidentally, it is particularly possible for the circular disc to at least partially protrude from the depression. The circular-type disc is arranged in the depression only in places then.

The connecting flange may be formed with the two segments. The two segments may then be configured to be mirror-symmetrical to one another within the manufacturing tolerances. The depression is arranged between the segments. Each segment comprises a recess, with the two recesses of the segment together forming the recess. Furthermore, each segment comprises a groove with the sealing element attached to the side surfaces. The circular-type-shaped disc may be squeezed between the two segments in the depression then.

The connecting flange may be formed integrally and with a plastic material. The connecting flange is a rubber mat having a horizontal slot, through which the circular-type disc can be inserted in the rubber mat.

The method, the device and the pumping device described herein are explained in greater detail below by examples in conjunction with the figures.

Identical, like or similar elements are indicated with the same reference numerals throughout the figures. The figures and the size ratios of the elements illustrated in the figures relative to one other are not to be considered as true to scale. Rather, individual elements can be illustrated in an exaggerated size for the purpose of a better understanding.

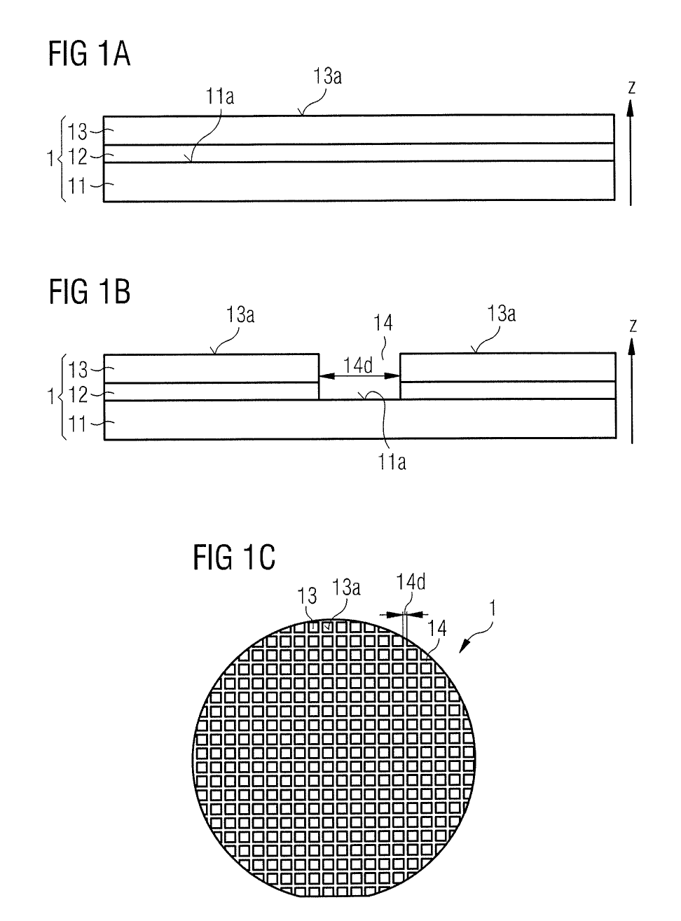

A first method step of a method described herein is explained by the schematic sectional view of FIG. 1A. In the illustrated method step, first a wafer 1 having a substrate 11 comprising a growth surface 11a, a sacrificial layer 12 and the epitaxially-grown layer sequence 13 comprising a cover surface 13a facing away from the substrate 11 is provided. The layer sequence 13 is arranged on a growth surface 11a, with the sacrificial layer 12 arranged in a vertical direction Z between the substrate 11 and the layer sequence 13. The sacrificial layer 12 may be directly adjacent to the growth surface 11a and/or the layer sequence 13 here.

A further method step of a method described herein is explained in greater detail by the schematic sectional illustration of FIG. 1B. Separating trenches 14 are produced through the layer sequence 13 and the sacrificial layer 12, the trenches extending in the vertical direction Z completely through the layer sequence 13 and the sacrificial layer 12 all the way to the growth surface 11a of the substrate 11. The separating trenches 14 are produced using an etching method, for example. The separating trenches 14 have a width 14d in a lateral direction running perpendicular to the vertical direction Z.

FIG. 1C shows the method step illustrated in FIG. 1B by a schematic top view of wafer 1 from the vertical direction Z. The wafer 1 is configured in the type of a circular disc in this case. In particular, the wafer 1 has a circular cross section with a flattening on the illustrated lower edge of the wafer 1.

Separating trenches 14 are of continuous and contiguous design. The separating trenches 14 enclose regions of the layer sequence 13 in a frame-like manner. The regions of the layer sequence 13 enclosed by the separating trenches 14 may have the shape of the semiconductor chips to be produced here.

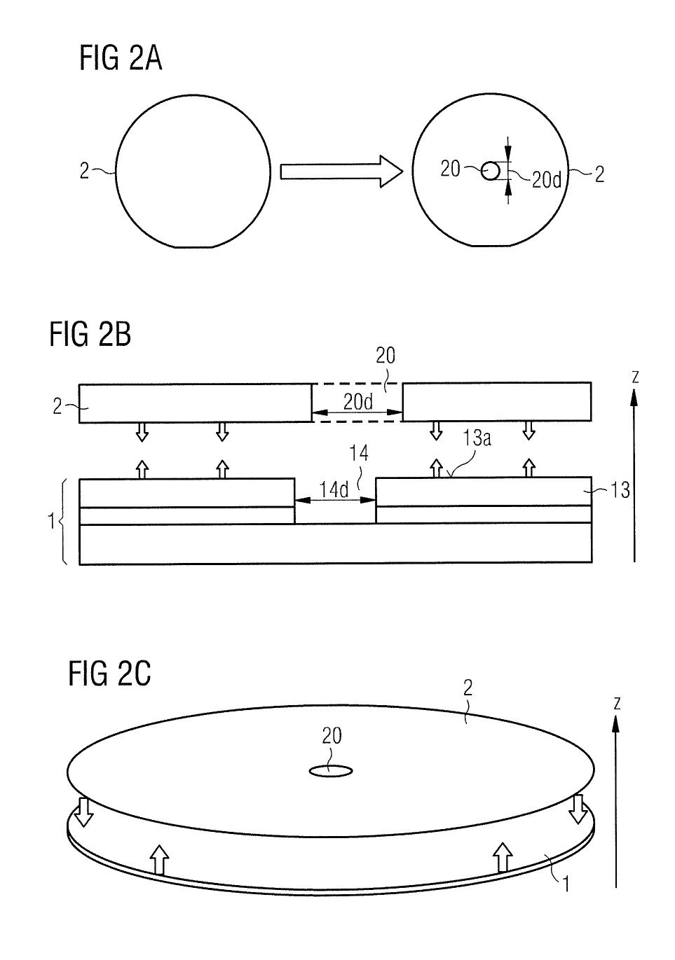

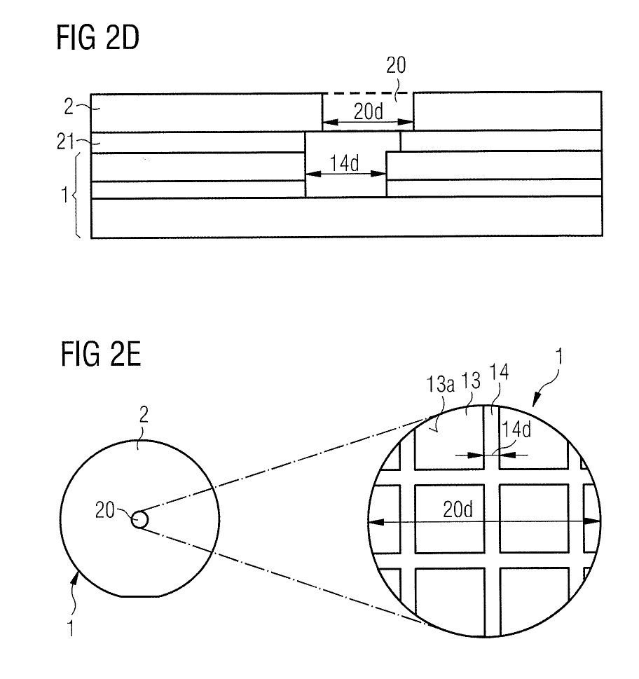

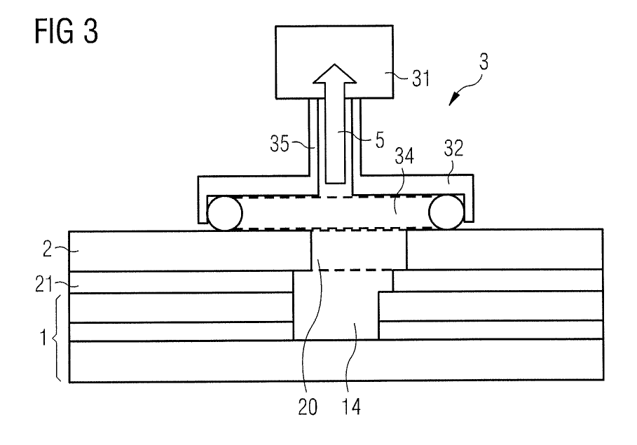

A further method step of a method described herein is explained in more detail by the schematic top view from the vertical direction Z of FIG. 2A. In the illustrated method step, a carrier 2 is provided having a shape and lateral dimensions similar to the ones of the wafer 1. In other words, the carrier 2 can also be of circular-disc-shaped design and the diameter of the carrier 2 may deviate from the diameter of wafer 1 by at most +/−10%. A hole 20 is introduced in the center 22 of the carrier 2. The hole 20 has circular design and a diameter 20d. The hole 20 may also have a different geometrical shape, e.g. a polygonal shape and/or may not be arranged at the center 22. Furthermore, it is possible for the carrier 2 to comprise multiple holes 20. The hole 20 extends completely through carrier 2 in the vertical direction Z.

A further method step of a method described herein is explained by the schematic sectional view of FIG. 2B and the schematic view of FIG. 2C. The carrier 2 is attached to the wafer 1 on the cover surface 13a of the layer sequence 13 particularly in a congruent fashion. In this case, it is possible for the hole 20 to be arranged offset to the separating trenches 14 in the vertical direction Z. In other words, the separating trenches 14 can be arranged decentralized in relation to the hole 20. Attachment is effected by a solder connection, for example.

A further method step of a method descried herein is explained in greater detail by the schematic sectional illustration of FIG. 2D. The illustrated method step shows a described composite 1, 2 of a wafer and a carrier 2. The wafer 1 and the carrier 2 connect to one another by a solder layer 21, which 1 may directly adjoin the wafer 1 and/or the carrier 2. The separating trenches 14 are free of the solder layer 21 here.

The microscopic picture of FIG. 2E shows the composite 1, 2 produced in method steps 2B to 2D. On the left side, the composite 1, 2 is illustrated in a top view from the vertical direction Z. On the right side, an enlarged view of hole 20 in the carrier 2 of composite 1, 2 taken by a microscope is illustrated. The wafer 1 having the layer sequence 13 and the separating trenches 14 can be discerned through the hole 20. The diameter 20d of hole 20 is substantially larger than the width of separating trenches 14. In particular, multiple separating trenches 14 are freely accessible through the hole 20.

By the schematic illustration of FIG. 3, a method described herein and a pumping device 3 described herein are explained in greater detail. The pumping device 3 is attached to the composite 1, 2 of wafer 1 and carrier 2. The pumping device 3 comprises a circular-type-shaped connecting flange 32 with an O-ring 34 laterally enclosing the hole 20. The O-ring 34 is directly adjacent to the carrier 2. The connecting flange 32 connects to a vacuum pump 31 via a vacuum hose 35. A pressure gradient 5 from the separating trenches 14 through the hole 20 to the vacuum pump 31 can be generated by vacuum pump 31.

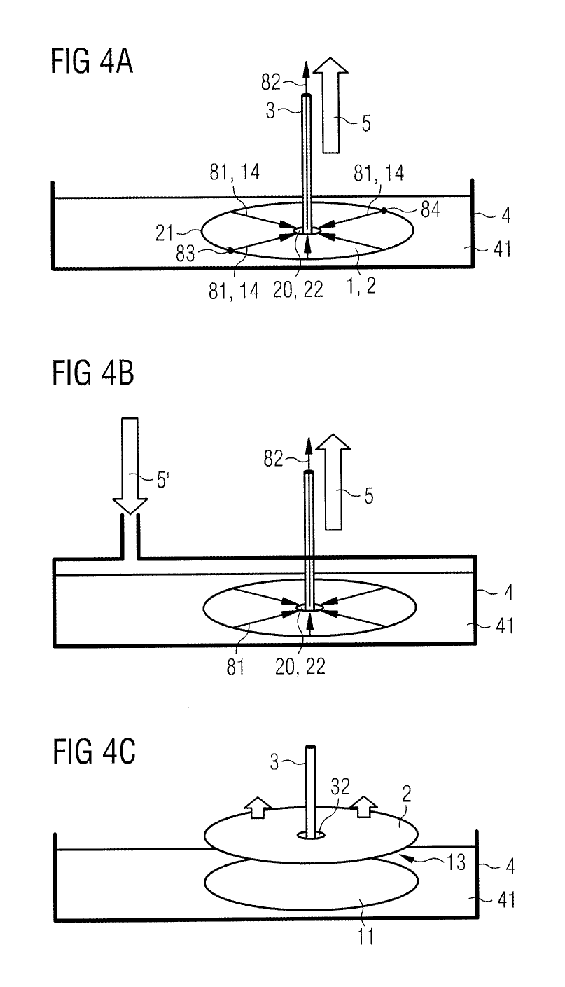

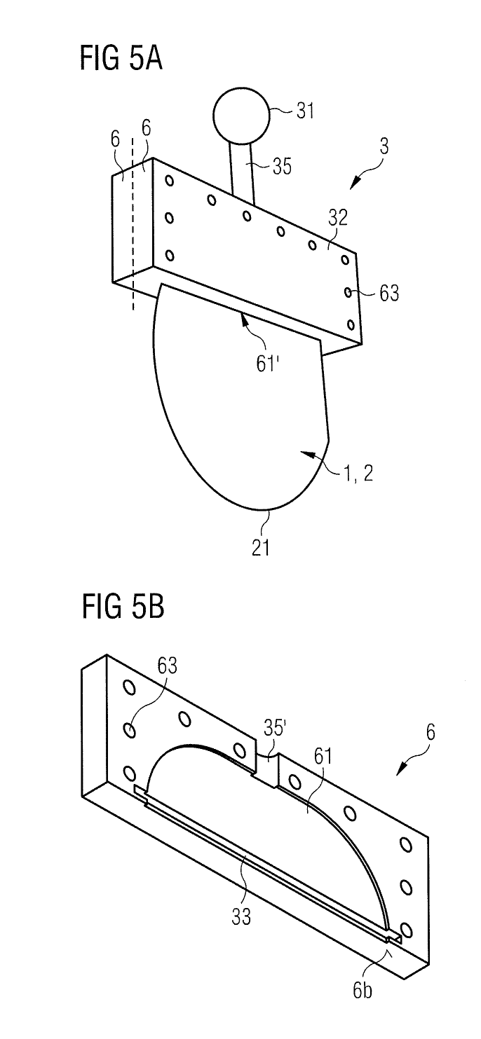

By the schematic illustration of FIG. 4A, a described method is explained in greater detail. In the method step described, the composite 1, 2 is introduced into an etching bath 4 with an etching solution 41. Furthermore, a pressure gradient 5 is generated between the separating trenches 14 and the pumping device 3. In this case, a negative pressure is generated in the composite 1, 2, by suctioning with the pumping device 3.

The first direct flow path 81 is formed between the first edge point 83 or the second edge point 84 and the center 22, which in this case is the inner point 22. Also, a second direct flow path 82 is formed from the center 22 and the pumping device 3. In particular, the first direct flow path 81 and the second direct flow path 82 connect to one another. Due to the pressure gradient 5, the etching solution 41 can be pumped through the first edge point 83 or the second edge point 84 into the direct flow path 81 and subsequently be pumped into the second direct flow path 20 via the hole 20 to the pumping device 3.

An alternative method step of a method described herein is explained by the schematic illustration of FIG. 4B. The illustrated method step corresponds the one of FIG. 4A, wherein in addition to generation of the pressure gradient 5 with a negative pressure, a further pressure gradient 5′ is generated with an overpressure. To that end, the etching solution 41 can be pumped or respectively pressed into the direct flow paths 81, 82 by a compressor (not illustrated here), for example. It is possible here for the etching solution 41 to both be suctioned into the flow paths 81, 82 by the pressure gradient 5 and be pumped into the flow paths 81, 82 by the further pressure gradient 5′.

A further method step of a method described herein is explained in more detail by the schematic sectional illustration of FIG. 4C. In the method step illustrated here, the substrate 11 is debonded from the carrier 2 comprising the layer sequence 13. To that end, the carrier 2 with the layer sequence 13 is removed (see indicated arrows) from the substrate 11. The pumping device 3 can be used to that end here as well. The carrier 2 can be suctioned-off from the substrate 11, for example.

A pumping device 3 described herein is explained in greater detail by the schematic illustrations of FIG. 5A. The pumping device 3 comprises a connecting flange 32 having two segments 6 connected in a mechanically-releasable manner by threaded bores 63. Fitting pins, screws and/or threaded pins are guided through the threaded bores 63 to that end, for example. Segments 6 are in particular designed to be mirror-symmetrical to one another. The connecting flange 32 further comprises a connection to a vacuum pump 31 via a vacuum hose 35. The composite 1, 2 is introduced in a depression 61′ of the connecting flange 32. The composite 1, 2 is clamped between the two segments 6 to that end, for example.

A pumping device 3 described herein is explained in greater detail by the schematic illustration of FIG. 5B. FIG. 5B shows a segment 6 of the connecting flange 32 illustrated in FIG. 5A. Segment 6 comprises a recess 61 having a circular-segment-type cross section. The recess 61 particularly partially receives the composite 1, 2, as illustrated in FIG. 5A. The recess 61 comprises a groove 33 arranged on the chord of the circular-segment-type cross section. The groove is arranged on the side surface 6b of the connecting flange 32, in particular. The groove 33 receives the O-ring 34 here. Furthermore, the connection to the vacuum hose 35′ is attached on the side of the recess 61 opposite the groove.

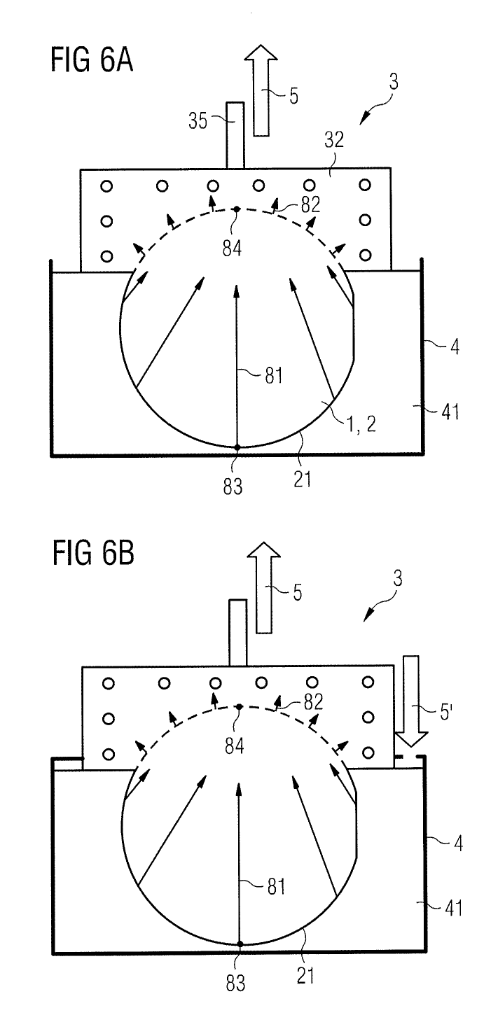

A further example of a method described herein is explained in greater detail by the schematic illustrations of FIGS. 6A and 6B. In the illustrated method, the pumping device 3 connects laterally to the composite and the composite 1, 2 is immersed into the etching solution 41 laterally. To that end, the composite 1, 2 is clamped into a connecting flange 32 illustrated in FIGS. 5A and 5B. The composite is laterally introduced into the etching solution on the side of the composite opposing the center 22. Preferably, at least 50% of the composite 1, 2 is covered by the etching solution here.

It is possible for the composite 1, 2 to be rotated in the connecting flange during the method to ensure a uniform wetting of the composite 1, 2 with the etching solution 41.

In the illustrated example, the pressure gradient 5 is generated on the edge 21 of the composite 1, 2. The first direct flow path 81 leads from the first edge point 83 of composite 1, 2 to the second edge point 84 of composite 1, 2 then, which is arranged opposite the first edge point 83 with respect to the center. In a lateral attachment of the pumping device 3, a further pressure gradient 5′ with an overpressure can also be generated (see illustration of FIG. 6B to that end).

The method described herein, the device described herein and the pumping device described herein are particularly characterized by their simple integration into the existing process. The advantageous reduction in process time compensates the partial destruction of the carrier caused by the production of the hole.

This application claims priority of DE 10 2014 115 799.0, the subject matter of which is incorporated herein by reference.

Our devices and methods are not limited to the examples by the description of these examples. This disclosure rather comprises every new feature as well as every combination of features, which in particular includes every combination of features in the appended claims, even if the feature or combination is per se not explicitly indicated in the claims or the examples.

1.-18. (canceled)

19. A method of debonding a substrate from a layer sequence comprising:
a) providing a composite comprising
a wafer with the substrate, the layer sequence applied to a growth surface of the substrate and provided for implementation in a light-emitting diode chip, and a sacrificial layer arranged between the substrate and the layer sequence,
a carrier on a cover surface of the layer sequence facing away from the substrate, and
at least two separating trenches extending in the vertical direction through the layer sequence and to and/or through the sacrificial layer, wherein
at least one first direct flow path runs through the at least two separating trenches from a first edge point on an exposed edge of the composite to an inner point of the composite,
b) attaching a pumping device on the composite and forming a second direct flow path between the separating trenches and the pumping device,
c) introducing the composite into an etching bath with an etching solution, wherein the composite is covered by the etching solution at least in places, and at least one separating trench on the edge is completely in direct contact with the etching solution,
d) generating a pressure gradient between the separating trenches and the etching solution with the pumping device such that the etching solution flows through the two direct flow paths in places along the sacrificial layer, wherein the etching solution is in places in direct contact with the sacrificial layer, and
e) debonding the substrate, wherein
prior to step b), exactly one hole is produced in the carrier and/or the layer sequence, and the pumping device connects to the hole in step b), the hole extends completely through the carrier and the layer sequence in a vertical direction and is introduced in the carrier and in the layer sequence at a center of the composite, and at least the second flow path runs through the hole.

20. The method according to claim 19, wherein the at least one first direct flow path is further guided to a second edge point from the inner point of the composite through at least one of the at least two separating trenches, and the second edge point is arranged on the side of the edge opposite the first edge point with respect to the center of the composite.

21. The method according to claim 19, wherein the process time of steps b) to d) required to completely debond the substrate totals up to 1 hour.

22. The method according to claim 19, wherein the process time of steps b) to d) required to completely debond the substrate is at most half of the process time required to completely debond the substrate with a method in which no pressure gradient is generated in step c).

23. The method according to claim 19, wherein a negative pressure is generated in the separating trenches to generate the pressure gradient in step d).

24. The method according to claim 19, wherein a positive pressure is generated in the etching solution to generate the pressure gradient in step d).

25. The method according to claim 19, wherein the etching solution is or includes a gaseous etching medium.

26. The method according to claim 19, wherein each separating trench has a width of at least 0.2% and at most 50% of a diameter of the at least one hole.

27. The method according to claim 19, wherein the pumping device laterally connects to the composite, and the first flow path and the second flow path runs through at least 10% of the edge of the composite.

28. A device that performs the method of claim 19, the device comprising:
a pumping device having
a vacuum pump, and
at least one connecting flange connected to the vacuum pump and comprising at least one sealing element, and
an etching bath with an etching solution, wherein
the method comprises:
a) providing a composite comprising a wafer with the substrate, the layer sequence, a sacrificial layer arranged between the substrate and the layer sequence, and at least two separating trenches extending in a vertical direction through the layer sequence and to or through the sacrificial layer,
b) attaching a pumping device on the composite,
c) introducing the composite into the etching bath,
d) generating a pressure gradient between the separating trenches and the etching solution with the pumping device, and
e) debonding the substrate,
the sealing element has a good chemical resistance toward the material of the etching solution, and
the vacuum pump is configured to generate a pressure of at most 10³ Pa, in the volume generated by the separating trenches.

29. The device according to claim 28, wherein the connecting flange comprises two segments, wherein
each segment comprises a recess, wherein at least one recess has a circular-segment-type shape in a top view,
the two segments connect with one another in a mechanically releasable manner on their connection surfaces comprising the respective recess, and
the connecting flange is configured to receive the composite partially between the two segments in the two recesses and to seal it toward the outside.

30. The device according to claim 29, wherein the two segments are configured mirror-symmetrical to one another within the manufacturing tolerances.

31. The device according to claim 28, wherein the carrier and the layer sequence comprise exactly one hole, and the hole extends completely through the carrier and the layer sequence in a vertical direction and the connecting flange has a circular-type design in a top view and is configured to completely enclose the hole laterally with the sealing element and seal it toward the outside.

32. A pumping device that pumps etching solution in the method of claim 19, comprising:
a vacuum pump and
a connecting flange connected to the vacuum pump via a vacuum hose, wherein
the connecting flange comprises a depression having a circular-segment-type cross section,
the depression extends entirely to an exposed side surface of the connecting flange, wherein the chord of the circular-segment-type cross section is part of the side surface and
the connecting flange comprises a sealing element in the depression attached to the side surface.

33. The pumping device according to claim 32, wherein the connecting flange comprises two segments, wherein
the depression is arranged between the two segments,
each segment comprises a recess,
the recesses of the segments together form the depression, and
each segment comprises the sealing element attached to the side surface.

34. The pumping device according to claim 33, wherein the two segments are configured mirror-symmetrical to one another within the manufacturing tolerances and the recesses in the segments have circular-segment-type shape in a top view.

35. The pumping device according to claim 32, wherein the connecting flange is formed integrally and with of a synthetic material.
